(19) United States
(12) Patent Application Publication
(10) Pub. No.: US 2009/0169781 A1
(43) Pub. Date: Jul. 2, 2009

(54) Low thermal conductivity low density pyrolytic boron nitride material, method of making, and articles made therefrom

(76) Inventors: Marc Schaepkens, Clifton Park, NY (US); Demetrius Sarigiannis, Grand Island, NY (US); Douglas Longworth, Brecksville, OH (US)

Correspondence Address: DILWORTH & BARRESE, LLP, 1000 WOODBURY ROAD, SUITE 405, WOODBURY, NY, 11797, US

(21) Appl. No.: 12/006,206

(22) Filed: Dec. 31, 2007

(51) Int. Cl. C01B 21/064; C23C 16/34; B32B 1/08

(52) U.S. Cl. 428/34.4; 423/290; 427/255.38

(57) ABSTRACT

A pyrolytic boron-nitride material is disclosed having an in-plane thermal conductivity of no more than about 30 W/m-K and a through-plane thermal conductivity of no more than about 2 W/m-K. The density is less than 1.85 g/cc.

### BACKGROUND

1. Field of the Invention

The present invention relates to a pyrolytic boron nitride material, a method for making the material, and articles made therefrom.

2. Background of the Art

Boron nitride (BN) is typically formed into articles of manufacture. Boron nitride (BN) is a well-known, commercially produced refractory non-oxide ceramic material. Pyrolytic boron nitride (p-BN) can be made by chemical vapor deposition (CVD) onto a substrate such as graphite. The most common structure for BN is a hexagonal crystal structure. This structure is similar to the carbon structure for graphite, consisting of extended two-dimensional layers of edge-fused six-membered (BN)₃ rings. The rings arrange in crystalline form where B atoms in the rings in one layer are above and below N atoms in neighboring layers and vice versa (i.e., the rings are shifted positionally with respect to layers). The intraplanar B—N bonding in the fused six-membered rings is strongly covalent while the interplanar B—N bonding is weak, similar to graphite. The layered, hexagonal crystal structure results in anisotropic physical properties that make this material unique in the overall collection of non-oxide ceramics.

Crucibles used in the Czochralski (LEC), Horizontal Bridgeman (HB), or Vertical Gradient Freeze (VGF) methods of making single crystals of compound semiconductor including gallium arsenide semiconductor, can be made from p-BN. See, for example U.S. Pat. No. 5,674,317 to Kimura et al. which discloses a vessel made from pyrolytic boron nitride having a density of from 1.90 to 2.05 g/cc.

An advantage of p-BN is its anisotropy. In the above-mentioned methods of single crystal semiconductor material production, it is important to carefully control the thermal gradients in the melt to reduce the risk of crystal defects which could render the semiconductor unsuitable for its intended use in chip manufacture. The thermal conductivity of boron nitride is greater along the crystal plane than through the crystal plane. This anisotropy favors a highly uniform temperature profile in the molten semiconductor material in the crucible, but it limits the control over thermal gradients which may be required for production of optimum crystals. Therefore, it is preferable to have as low a thermal conductivity as possible in both the in-plane and through plane directions of the crucible to maintain temperature uniformity throughout all of the semiconductor melt.

### SUMMARY

Provided herein is a pyrolytic boron nitride material having an in-plane thermal conductivity of no more than about 30 W/m-K and a through-plane thermal conductivity of no more than about 2 W/m-K. The p-BN material of the invention preferably has a density of less than 1.85 g/cc, which is lower than standard p-BN.

Advantageously, the p-BN material of the invention has high exfoliation resistance and provides greater thermal control of semiconductor melt in crucibles made therefrom than regular p-BN.

### BRIEF DESCRIPTION OF THE DRAWINGS

Various embodiments are described below with reference to the drawings wherein:

FIG. 1 is a graph showing a comparison between the in-plane thermal conductivity of standard prior art p-BN crucibles (std) and the novel ultra low density (uld) p-BN crucibles of the invention;

FIG. 2 is a graph showing the relationship of through plane (i.e., c-direction) thermal diffusivity as measured by the laser flash method vs. temperature for the p-BN of the invention as compared with regular and layered p-BN;

FIG. 3 is a graph showing the relationship of heat capacity vs. temperature for the p-BN of the invention as compared with regular and layered p-BN; and

FIG. 4 is a graph showing the relationship of through plane (c-direction) thermal conductivity vs. temperature for the p-BN of the invention as compared with regular and layered p-BN.

### DETAILED DESCRIPTION OF PREFERRED EMBODIMENT(S)

Other than in the working examples or where otherwise indicated, all numbers expressing amounts of materials, reaction conditions, time durations, quantified properties of materials, and so forth, stated in the specification are to be understood as being modified in all instances by the term “about.”

It will also be understood that any numerical range recited herein is intended to include all sub-ranges within that range.

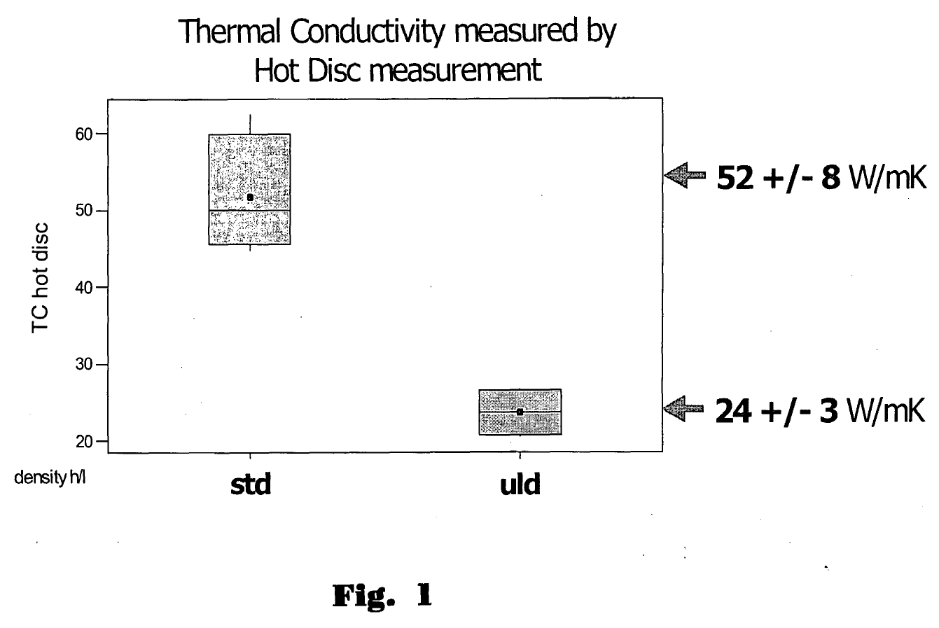

Referring now to FIG. 1, the standard p-BN crucibles of the prior art typically exhibit an in-plane thermal conductivity of about 52 W/m-K. However, in one embodiment the pyrolytic boron nitride (p-BN) of the invention possesses an in-plane thermal conductivity of no more than about 30 W/m-K and a through-plane thermal conductivity of no more than about 2 W/m-k. In another embodiment, the p-BN of the invention possesses an in-plane thermal conductivity of no more than about 24 W/m-K and a through-plane thermal conductivity of no more than about 1.1 W/m-k. In yet another embodiment of the invention the p-BN possesses an in-plane thermal conductivity of no more than about 20 W/m-K and a through-plane thermal conductivity of no more than about 0.7 W/m-k. The aforementioned values of thermal conductivity are given for p-BN at room temperature.

Moreover, in an embodiment the p-BN of the invention possesses a density of less than 1.85 g/cc, and in another embodiment the p-BN of the invention possesses a density of no more than about 1.81 g/cc.

The p-BN of the invention is less crystalline and less oriented than standard density regular p-BN, which provides greater exfoliation resistance. The degree of orientation is defined by the equation

I Ratio=I[002]_{WG}/I[100]_{WG}

in which I[002]_{WG} and I[100]_{WG} are each the relative intensity of the X-ray diffraction peaks assignable to the crystallographic [002] plane having a lattice spacing of 0.333 nm and the [100] plane having a lattice spacing of 0.250 nm, respectively, in the X-ray diffraction spectrum taken with X-ray beams incident in a direction perpendicular to the a-plane, i.e. a plane parallel to the layers forming the laminar structure of the vessel walls (with the grain). The p-BN of the invention is characterized by I-ratios ranging from about 35-75, which are lower than the I-ratios of higher density regular p-BN, which typically range from about 110 to 210.

Another measurement of the degree of orientation is the I[002]_{WG} value which is less sensitive to variability in sample preparation than the I-ratio. Table 3 below shows that the ultra low density (ULD) p-BN of the invention is characterized by a lower degree of orientation, wherein cps refers to counts per second, FWHM refers to full width at half maximum intensity, and the area refers to area under the rocking curve.

TABLE 3
(Values of I[002]_{WG})

| Sample | cps | FWHM | Area (cps*^{o}) |
|---|---|---|---|
| ULD p-BN | 2.78 | 1.41 | 5.05 |
| Regular p-BN | 5.63 | 1.06 | 7.36 |

The p-BN of the invention is made by chemical vapor deposition (CVD) under reaction conditions suitable for providing a deposition rate of p-BN on a substrate (e.g., graphite substrate) of at least about 0.001 inches/hr, preferably at least about 0.0015 inch/hr and more preferably at least about 0.002 inch/hr. The reactants introduced into the CVD reaction zone include ammonia and a boron halide (BX₃) such as boron chloride, BCl₃, or boron trifluoride, BF₃. Typically the reactants are introduced separately in the CVD reactor at a NH₃/BX₃ ratio of from about 2:1 to about 5:1. The reaction conditions include a temperature of less than 1,800° C. and a pressure of from about 1.0 Torr to about 0.1 Torr. In another embodiment the temperature is less than 1700° C. and a pressure of from about 1.0 Torr to about 0.1 Torr. The flow rate of the reactants is a significant feature of the invention and is selected in conjunction with the reactor volume to provide the deposition rate set forth above. Typical reactor volumes and preferred accompanying reactant flow rates are set forth in Table 1 below. The ranges given are for the purpose of exemplification and are not to be construed as limitations on the scope of the invention.

TABLE 1

| | Range of values for | Range of values for the |
|---|---|---|
| Reactor Volume | ammonia flow rate (liters | boron halide flow rate |
| (cubic inches) | per minute) | (liters per minute) |
| 6,000 | From about 3.0 to about | From about 1.5 to about 3.0 |
| | 8.0 | |
| 30,000 | From about 4.0 to about | From about 2.0 to about 4.0 |
| | 10.0 | |

The p-BN of the invention possesses advantageous properties in comparison with regular p-BN as illustrated by the following Examples.

### EXAMPLES

### Example 1

Eight samples of standard density p-BN and 11 samples of ultra low density (ULD) p-BN produced in accordance with the method described herein were tested for density using helium pycnometry. The samples were obtained by cutting small pieces of p-BN from VGF crucibles deposited on graphite mandrels at conditions described below. The ULD p-BN was provided under reaction conditions including a temperature of 1750° C., a pressure of 0.35 Torr, BCl₃ flow rate of 2.4 liters per minute, an ammonia flow rate of 6.5 liters per minute and nitrogen flow rate of 0.50 liters per minute.

TABLE 2
(Comparison of densities of standard density p-BN and ULD p-BN)

| Anderson-Darling Normality | Standard Density | |
|---|---|---|
| Test | p-BN | ULD p-BN |
| A-Squared | 0.679 | 0.485 |
| P-Value | 0.041 | 0.179 |
| Mean density (g/cc) | 2.06787 | 1.81400 |
| Standard deviation | 0.04126 | 0.05802 |
| Variance | 1.7E−03 | 3.37E−03 |
| Skewness | −1.09583 | −1.11017 |
| Kurtosis | −3.6E−01 | 0.815525 |
| N | 8 | 11 |
| Minimum | 2.00000 | 1.69000 |
| 1^{st} Quartile | 2.02350 | 1.77500 |
| Median | 2.08200 | 1.83000 |
| 3^{rd} Quartile | 2.10125 | 1.85000 |
| Maximum | 2.10600 | 1.88600 |
| 95% Confidence Level for Mu | 2.03338-2.10237 | 1.77502-1.85298 |
| 95% Confidence Level for | 0.02728-0.08398 | 0.04054-0.10182 |
| Sigma | | |
| 95% Confidence Level for | 2.00749-2.10506 | 1.77204-1.85140 |
| Median | | |

### Example 2

Eight samples of standard density regular p-BN, layered p-BN, and the ULD p-BN of the invention were measured for thermal diffusivity and heat capacity. The samples were produced in a CVD process and cut from the top end of the crucibles. The layered p-BN was produced by pulsing a doping gas. The layered p-BN has a higher density and different material properties (TC, mechanical strength, crystallinity, and orientation). Layering reduces exfoliation resistance. Measurements were conducted by laser flash, diffusivity and hot disc methods. The thermal conductivity was calculated according to the equation

$$α = \frac{k}{ρ \cdot {c}_{p}}$$

wherein:
α is thermal diffusivity,
k is thermal conductivity,
ρ is density, and
Cₚ is heat capacity

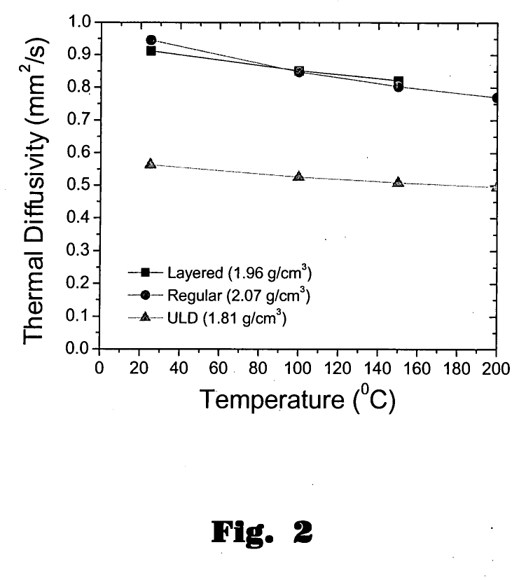

Referring now to FIG. 2, a comparison of through plane (c-direction) thermal diffusivity (mm²/s) is presented for regular p-BN having a density of 2.07 g/cc, a layered p-BN having a density of 1.96 g/cc, and the ULD p-BN of the invention having a density of 1.81 g/cc. As can be seen, the thermal diffusivity of the ULD p-BN is below 0.6 across the entire range range of temperatures at which the samples were tested. In contrast to this, the layered and regular p-BN were above 0.75 across the temperature range.

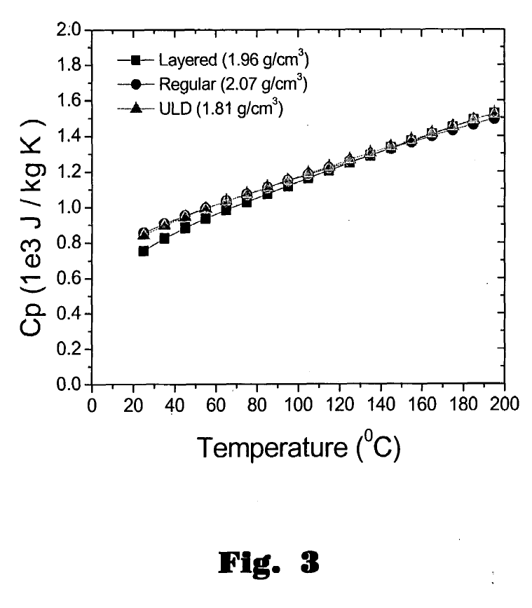

Referring to FIG. 3, the regular, layered, and ULD p-BN exhibited similar heat capacities along the temperature range.

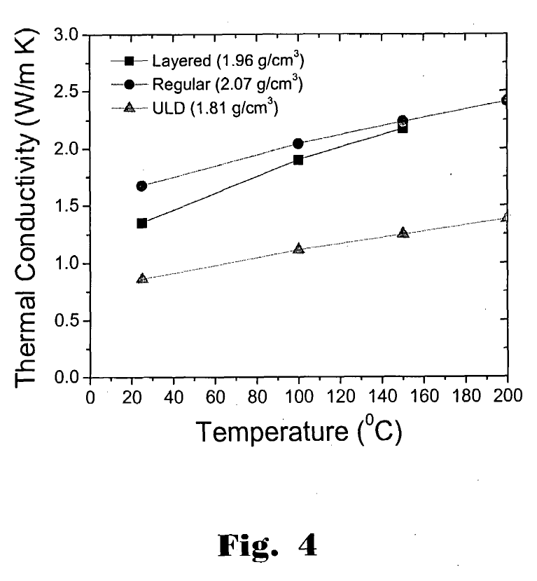

Referring to FIG. 4, the through-plane thermal conductivities of the regular, layered and ULD p-BN were calculated according to the equation set forth above. As can be seen, the through-plane conductivity for the ULD p-BN was far below the thermal conductivities of both the regular and layered samples. For example, at 20° C. the ULD p-BN of the invention had a through-plane conductivity of about 0.85 W/m-K whereas the layered p-BN had a through-plane thermal conductivity of about 1.35 W/m-K and the regular p-BN had a through-plane thermal conductivity of about 1.7 W/m-K. At 200° C. the ULD p-BN of the invention had a through-plane thermal conductivity of about 1.35 W/m-K whereas the regular p-BN had a through-plane thermal conductivity of about 2.4 W/m-K.

The ULD p-BN material of the invention is advantageously used for the manufacture of crucibles as well as vessels for molecular beam epitaxy, heaters for electrostatic chucks, and other applications wherein pyrolytic boron nitride is typically used.

While the above description contains many specifics, these specifics should not be construed as limitations of the invention, but merely as exemplifications of preferred embodiments thereof. Those skilled in the art will envision many other embodiments within the scope and spirit of the invention as defined by the claims appended hereto.

What is claimed is:

1. A pyrolytic boron nitride material having an in-plane thermal conductivity of no more than about 30 W/m-K and a through-plane thermal conductivity of no more than about 2 W/m-K.

2. The pyrolytic boron nitride material of claim 1 possessing a density of less than 1.85 g/cc.

3. The pyrolytic boron nitride material of claim 1 wherein the in-plane conductivity is no more than about 24 W/m-K and the through-plane conductivity is no more than about 1.1 W/m-K.

4. The pyrolytic boron nitride material of claim 1 wherein the density of said material is no more than about 1.81 g/cc.

5. The pyrolytic boron nitride material of claim 1 wherein the in-plane conductivity is no more than about 20 W/m-K and the through-plane conductivity is no more than about 0.7 W/m-K.

6. The pyrolytic boron nitride material of claim 1 wherein said boron nitride is characterized by an I-ratio of from about 35 to about 75.

7. The pyrolytic boron nitride material of claim 1, wherein said material is made by chemical vapor deposition at a temperature of less than 1,800° C.

8. The pyrolytic boron nitride material of claim 6, wherein the pyrolytic boron nitride is deposited on a substrate at a deposition rate of at least about 0.001 inch/hr.

9. The pyrolytic boron nitride material of claim 6, wherein said material is made by reaction of ammonia and a boron halide reactants in a CVD reaction zone.

10. The pyrolytic boron nitride material of claim 7 wherein reaction zone volume and reactant flow rates are selected to provide a deposition rate of at least about 0.001 inch/hr.

11. A vessel made from the pyrolytic boron nitride material of claim 1.

12. A process for making a particle from boron nitride comprising:
reacting ammonia and a boron halide in a chemical vapor deposition reaction zone under reaction conditions selected to provide a deposition rate of pyrolytic boron nitride onto a substrate of at least about 0.001 inch/hr.

13. The process of claim 9 wherein the reaction conditions include a temperature of less than 1,800° C.

14. The process of claim 10 wherein the flow rate of ammonia and boron halide and the reaction zone volume are selected to provide the deposition rate of at least 0.002 inch/hr.

15. The process of claim 14 wherein the ratio of the flow rate of ammonia to the flow rate of boron halide ranges from about 2:1 to about 5:1.

16. The process of claim 12 wherein the boron halide is boron trichloride.

17. The process of claim 12 wherein the reaction conditions include a temperature of less than 1700° C.

18. The process of claim 12 wherein the reaction conditions include a pressure of from about 1.0 Torr to about 0.1 Torr.

19. The process of claim 12 wherein the reaction zone has a volume of from about 6,000 cubic inches to about 30,000 cubic inches and the ammonia is introduced into the reaction zone at a flow rate of from about 3.0 to 10.0 liters per minute, and the boron halide is introduced into the reaction zone at a flow rate of from 1.5 to 4.0 liters per minute.

20. The process of claim 19 wherein the boron halide is boron trichloride, the reaction temperature is less than 1,800° C., and the pressure is from about 1.0 Torr to about 0.1 Torr.
